(19) United States
(12) Patent Application Publication
(10) Pub. No.: US 2024/0329125 A1
(43) Pub. Date: Oct. 3, 2024

(54) METHOD FOR POSITIONING SEMICONDUCTOR DEVICES AND CORRESPONDING POSITIONING APPARATUS

(71) Applicant: STMicroelectronics International N.V., Geneva (CH)

(72) Inventors: Moise AVOCI UGWIRI, Caserta (IT); Giuliano FILPI, Caserta (IT); Fabrice COSTE, Le Pontet (FR); Alex GRIMA, Xewkija (MT); Pedro Jr Santos PERALTA, Silang (PH)

(73) Assignee: STMicroelectronics International N.V., Geneva (CH)

(21) Appl. No.: 18/616,929

(22) Filed: Mar. 26, 2024

(30) Foreign Application Priority Data
Mar. 31, 2023 (IT) 102023000006327

(51) Int. Cl. G01R 31/28; H01L 23/00

(52) U.S. Cl. CPC G01R 31/2887; H01L 24/75; H01L 24/81; G01R 31/2896; H01L 2224/75745; H01L 2224/75756; H01L 2224/81136; H01L 2224/8118

(57) ABSTRACT

A method and apparatus for aligning electrical contact formations, such as bumps or solder balls, at a first surface of a Wafer Level Chip Scale Package (WLCSP) semiconductor device with electrically conductive pins in an array of electrically conductive pins such as “pogo” pins is provided. The semiconductor device includes, opposite the first surface, a second surface protected by a protection layer. The method includes aligning the semiconductor device to a first alignment member by exposing the protected second surface of the semiconductor device to a chamfered surface in the first alignment member. A second alignment member is aligned to the array of electrically conductive pins. The electrical contact formations are aligned with respect to the array of electrically conductive pins as desired in response to the first and second alignment members being mutually aligned, in response to the semiconductor device being “landed” onto the array of electrically conductive pins.

### BACKGROUND

### Technical Field

The present disclosure relates to a method for positioning semiconductor devices and a corresponding positioning apparatus for semiconductor devices.

For instance, embodiments as described herein can be applied in producing Wafer Level Chip Scale Package (WLCSP) integrated circuit semiconductor devices.

### Description of the Related Art

The designation Wafer Level Chip Scale Package (WLCSP) applies to a technology where integrated circuits are packaged at the wafer level, rather than as individual units after dicing them from a wafer.

The final device resulting from WLCSP processing is a semiconductor chip or die with an array of bumps or solder balls attached at an input/output pitch that facilitates circuit board assembly processes. The resulting package is thus essentially of the same size of the chip or die.

WLCSP technology advantageously dispenses with bond wires or similar connections and, in addition to a reduced package size, may also provide a reduced inductance from a die to a substrate (a printed circuit board, PCB, for instance).

One WLCSP category called “fan-in” limits redirection of solder balls to pads only on top of the chip, then sizing at the chip size, but also have no overmold then exposing chip substrate sidewall.

A problem that may arise in applying WLCSP technology is related to package insertion in test socket cavity when aligning (centering) a device on contact pins such as so-called “pogo” pins. These are electrical connectors that are used in view of their resilience to mechanical shock and vibration.

This handling might advantageously take place in a centering phase where a module is placed in a “personalization” socket taking advantage of auto-centering chamfers.

It is noted that applying such an approach to WLCSP devices may not be particularly attractive in so far as the right solution, as this may result in undesired damage of corner, sidewall, and active faces of the die.

This militates against personalizing (customizing) fan-in WLCSP packages when using reel-to-reel handling machines and using pick and place technology, for instance versus wafer level personalization before dicing.

### BRIEF SUMMARY

Solutions as described herein aim at addressing the issues discussed in the foregoing.

Such an object can be achieved via a method described herein.

One or more embodiments relate to a corresponding apparatus.

In solutions as described herein, a tool such as a vacuum cup can be used to pick up a die and to co-operate with a “nest” to facilitate mechanical pre-alignment at a nest level without unduly constraining placement accuracy at a “socket” level.

In that way, the edges of an alignment device may come into contact with the back or bottom side of the die, which is usually provided with a protective layer (coating), instead of coming into contact to the front or top (active) side, sidewall, or corner which are fragile.

Solutions as described herein facilitate pick and place sampling and preproduction activities, making these activities faster by enhancing alignment accuracy in comparison with conventional solutions, where sampling and preproduction are at wafer level, thus being expensive and hardly compatible with desired time-to-market strategies.

### BRIEF DESCRIPTION OF THE SEVERAL VIEWS OF THE DRAWINGS

One or more embodiments will now be described, by way of example only, with reference to the annexed figures, wherein:

FIG. 1 illustrates placing a semiconductor device in a personalization socket using auto-centering chamfers;

FIGS. 2 and 3 (where FIG. 3 is a view of a portion of FIG. 2 indicated by the arrow III) illustrate possible damage that might result from applying the solution of FIG. 1 to devices obtained via Wafer Level Chip Scale Package (WLCSP) technology;

FIG. 4 is a side view of a WLCSP device showing features that can be exploited in embodiments of the present disclosure;

FIGS. 5A to 5E illustrate steps in handling a semiconductor device according to embodiments of the present disclosure;

FIG. 6 illustrates a conventional personalization flow of a WLCSP device; and

FIG. 7 illustrates a personalization flow of a WLCSP device that can be facilitated by embodiments of the present disclosure.

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

### DETAILED DESCRIPTION

In the ensuing description one or more specific details are illustrated, aimed at providing an in-depth understanding of examples of embodiments of the disclosure. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present disclosure is intended to indicate that a particular configuration, structure, or characteristic described in relation to the embodiment is comprised in at least one embodiment. Hence, phrases such as “in an embodiment” or “in one embodiment” that may be present in one or more points of the present disclosure do not necessarily refer to one and the same embodiment.

Moreover, particular configurations, structures, or characteristics may be combined in any adequate way in one or more embodiments.

The headings/references used herein are provided merely for convenience and hence do not define the extent of protection or the scope of the embodiments.

For simplicity and case of explanation, throughout this description, and unless the context indicates otherwise, like parts or elements may be indicated in the various figures with like reference signs, and a corresponding description will not be repeated for each and every figure.

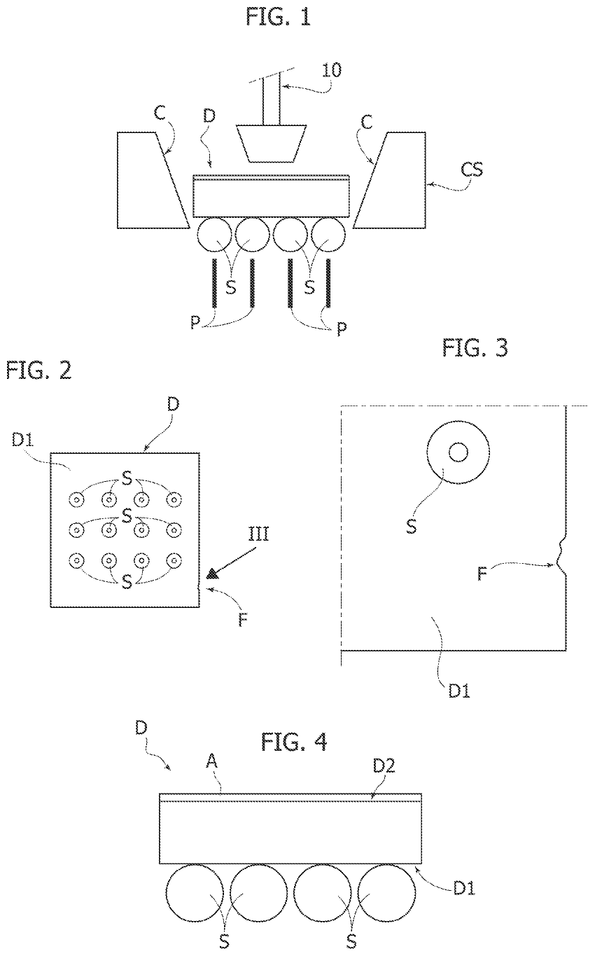

FIG. 1 illustrates placing an integrated circuit (IC) semiconductor device D in a “personalization” socket CS provided with auto-centering chamfers C.

This is essentially a mechanical centering method that can be implemented using a pick and place tool 10 (of a known type) that picks the semiconductor device D (from above in the case illustrated) and places, namely inserts or advances, the semiconductor device D in a personalization socket CS, taking advantage of auto-centering chamfers C provided therein.

Such an approach may be considered for centering a WLCSP device on pogo-pins P, namely electrical connectors that are used in view of their resilience to mechanical shock and vibration.

It is noted that applying such an approach to a WLCSP device may result in undesired damage F at the edge of the front or top surface, the sidewall or the corners of the chip or die as schematically illustrated in FIGS. 2 and 3, where FIG. 3 is a view of a portion of FIG. 2 indicated by an arrow III.

The final device resulting from WLCSP processing is a semiconductor chip or die (as used herein, these two terms are considered as synonymous) with an array of bumps or solder balls S attached to a front or top surface D1 in order to facilitate circuit board assembly processes (coupling to pogo-pins P, for instance).

In an arrangement as exemplified in FIG. 1, if applied to a WLCSP device, the edges of the alignment chamfers C will come into contact with the front or top (active) side, which may be fragile (bare silicon, for instance), thus possibly producing damage as exemplified by the reference F.

This militates against personalizing fan-in WLCSP packages using reel-to-reel handling machines using pick and place technology, for instance.

One or more embodiments are based on the recognition that the structure of a WLCSP device D may be as exemplified in FIG. 4 and thus include a device body having:

an—expectedly fragile—front or top surface D1 of unprotected silicon, for instance, carrying an array of bumps or solder balls S configured to facilitate circuit board assembly processes, by centered (aligned) mounting on a corresponding array of pogo-pins, for instance, and

a back or bottom surface D2 provided with a protective layer A (a coating of metal having a thickness of 20-25 microns, for instance).

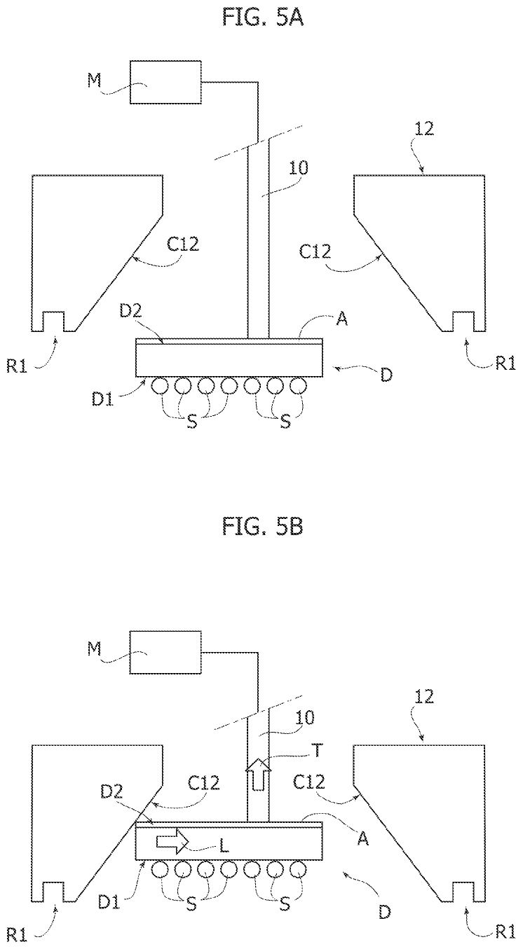

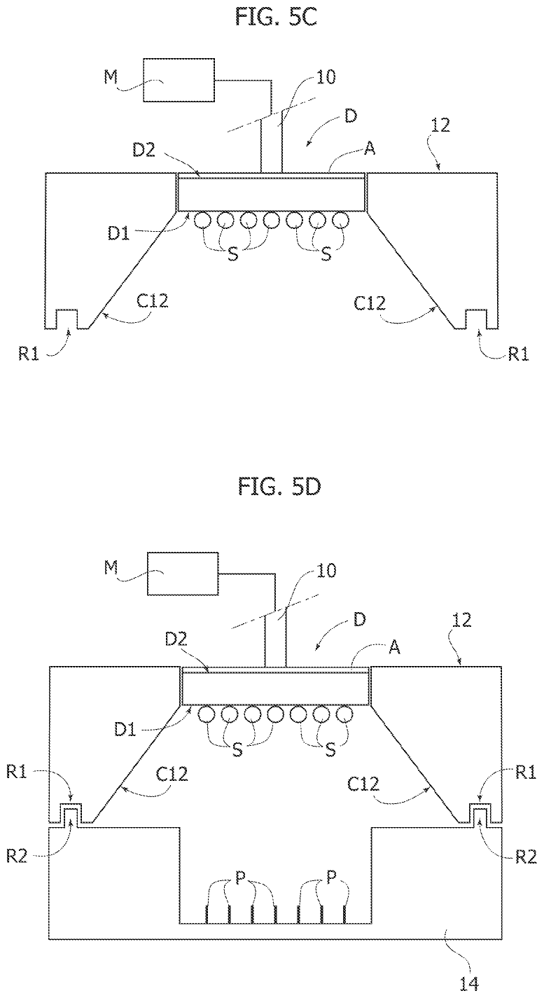

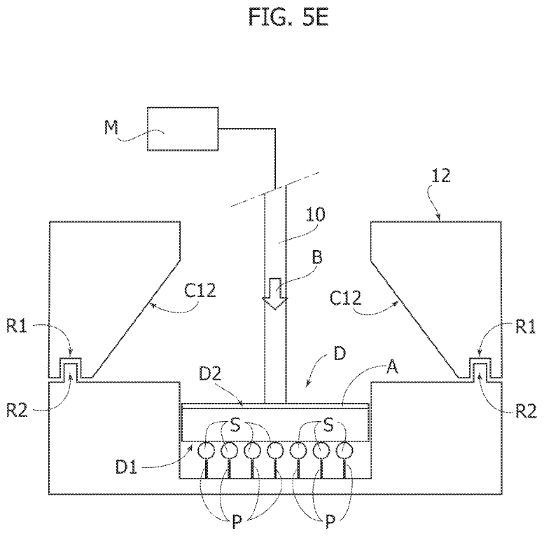

These features of a WLCSP device—essentially the fact that a WLCSP device D has (only) one “robust” and non-active surface (the coated back or bottom side D2)—can be exploited in handling a WLCSP device with the steps illustrated in FIGS. 5A to 5E, in order to align onto an array of pogo-pins P for electrical testing, for instance.

FIGS. 5A to 5E illustrate steps in aligning electrical contact formations (such as bumps or solder balls S in an array of electrical contact formations carried by a first surface D1 of a semiconductor device D) with electrically conductive pins in an array of electrically conductive pins such as “pogo” pins P.

As used herein, “aligning” is used to indicate the action of achieving a desired mutual positioning of electrical contact formations (bumps or solder balls, for instance) S and electrically conductive pins (“pogo” pins, for instance) P, in view of achieving electrical coupling.

While the wording “centering” may also be used in more common language, the wording “aligning” may represent a more accurate description of such a desired mutual positioning aiming at having an array of electrical contact formations facing a complementary array of electrically conductive pins lying in an adjacent plane.

In fact, while desired to be mutually positioned “in register” with each other, an array of electrical contact formations S and an array of electrically conductive pins P may not have a central point on a same axis.

One or more embodiments as exemplified in FIGS. 5A to 5E may take advantage of the fact that a semiconductor device D, such as the WLCSP device comprises, opposite the first surface D1, a second surface D2 protected by a protection layer such as the protective layer A.

It will be otherwise appreciated that the sequence of steps of FIGS. 5A to 5E is merely exemplary insofar as: one or more steps illustrated in FIGS. 5A to 5E can be omitted, performed in a different manner (with other tools, such as a pick-up tool 10 different from a vacuum cup, for instance), or replaced by other steps. Additional steps may also be added. One or more steps may be carried out in a sequence different from the sequence illustrated.

The steps illustrated in FIGS. 5A to 5E provide a mechanical alignment (centering) method that can be implemented using a pick and place tool 10 (such as a vacuum cup of a known type) that picks the device D (from above in the case illustrated) and aligns the device D with respect to a “nest” member 12.

As illustrated, such alignment (briefly, centering) is facilitated by chamfers C12 provided in the nest member 12.

As illustrated, the chamfers C12 are upwardly converging chamfers and the device D is aligned (centered) with respect to the nest member 12 by being pulled upwardly by the tool (vacuum cup) 10 as indicated by an upward arrow T at the top of FIG. 5B.

As illustrated, the chamfered surface C12 in the first alignment member (nest member) 12 comprises a tapered surface (frusto-conical, for instance) converging in a tapering direction (here, in the upward direction of the arrow T) from a first end at the bottom of the member 12 towards a second end at the top of the member 12.

As visible in FIGS. 5A to 5C, aligning the semiconductor device D to the first alignment member 12 may thus include picking—via a tool 10 such as a vacuum cup 10—the semiconductor device D (FIG. 5A) and advancing the semiconductor device D (picked at the second surface D2, here pointing upwardly) with respect to the chamfered surface C12 in the tapering direction thereof with the second surface D2 (protected by the protective layer A) exposed to the chamfered (tapered) surface C12.

In a positioning apparatus as illustrated in FIGS. 5A to 5E, such a pick-up advance/lifting movement (here exemplified by an arrow T in FIG. 5B) can be imparted to the tool 10 or the device D carried thereby via a motorization M (of a known type to those of skill in the art of pick and place machinery, for instance).

Alignment can thus take place during lifting the device D in response to the device D possibly sliding (in a lateral horizontal direction, for instance, here exemplified by an arrow L in FIG. 5B) under the picker tool 10 or with the picker tool 10 capable of moving correspondingly sidewise with respect to the nest member 12.

In that way, in response to the displacement with respect to the chamfered surface C12 of the nest member 12, the device (die) D can be adequately aligned (already) during the “pick” phase, with only the robust side (the back or bottom side D2 protected by the layer A) exposed to possible interaction (sliding, for instance) with the chamfers C12 (and with the picking tool 10).

Thanks to the perfect alignment of the nest member 12 and the device D, the risk of damage at the (fragile) surface D1 as exemplified by reference F in FIGS. 2 and 3 is thus effectively countered.

As illustrated in FIG. 5D, the nest member 12—having the device D adequately aligned therein (during the pick phase: see FIG. 5C), can be coupled, and thus aligned, with a mating socket member 14 to let the bumps or balls S in the device D finally “land” (FIG. 5E) on the pins P that are aligned (in a manner known per se to those of skill in the art) with the socket member 14.

In an apparatus as depicted in FIGS. 5A to 5E, such a landing movement can be in response to the picking tool 10 carrying the aligned (centered) device D being lowered towards the socket member 14 (and the pins P) as indicated by an arrow L in FIG. 5E via a motorization of a known type. This can be the same motorization M used for the picking/lifting movement T used for aligning the device D with the nest member 12 as illustrated FIG. 5A to 5C.

Provided the nest member 12 and the socket member 14 are properly mutually aligned, the device D—and, more to the point, the bumps or balls S at the underside of the device D—will land on the pogo-pins P in (precise) alignment therewith as desired, in view of subsequent coupling via soldering, for instance.

This result can be achieved by providing the nest member 12 and the socket member 14 with mating formations (“fiducials”) R1, R2 configured to facilitate (accurate) mutual alignment.

As illustrated, these fiducials R1, R2 may include cavities R1 at the (here lower) surface of the nest member 12 configured to be engaged by mating projections R2 (pins, for instance) at the (here upper) surface of the socket member 14.

In a complementary manner, these fiducials R1, R2 may include cavities at the surface of the socket member 14 configured to be engaged by corresponding mating projections (pins, for instance) at the adjacent surface of the nest member 12.

Also mixed arrangements, with the fiducials R1, R2 including cavities and projections carried by both the nest member 12 and the socket member 14 are feasible.

Advantageously, the fiducials R1, R2 may include self-centering mating features configured to mutually co-operate in a centering cone arrangement. In various embodiments, such features may include ramp formations protruding from the second alignment member (socket member 14) to engage the chamfered surface C12 in the first alignment member (nest member 12) in a centering cone arrangement.

Whatever the specific implementation of the mutual alignment features R1, R2, the device D (which is aligned with the nest member 12) and more to the point, the bumps or balls S at the first surface D1, will be aligned as desired with the pogo-pins P (which are aligned with the socket member 14).

To summarize, an apparatus as illustrated in FIGS. 5A to 5E may include a first alignment member (the nest member 12) and a second alignment member (the socket member 14) that configured to be coupled in a mutually aligned relationship (via centering features such as the “fiducials” R1, R2, for instance).

During the “pick” phase of FIGS. 5A to 5C, the semiconductor device D (and thus the formations S at the surface D1) are aligned to the first alignment member 12.

This can be achieved by exposing to the chamfered surface C12 in the nest member 12 (only) the second surface D2 of the device D, which is protected by the protective layer A.

As illustrated in FIGS. 5D and 5E, the second centering member (the socket member 14) is aligned with respect to the array of electrically conductive pins P.

As a result, the array of electrical contact formations (bumps or balls S) in the device D ends up by being aligned with respect to the array of electrically conductive pins P as desired in so far as the first alignment member (nest member 12) and the second alignment member (socket member 14) are mutually coupled.

As illustrated, this may take place in response to the device D being “landed” onto the pins P in an aligned relationship due to the presence of the complementary formations R1, R2, for instance, with the alignment members 12, 14 having in turn aligned therewith:

i) the array of electrical contact formations S in the semiconductor device D (in the case of the nest member 12), and

ii) the array of electrically conductive pins P (in the case of the socket member 14).

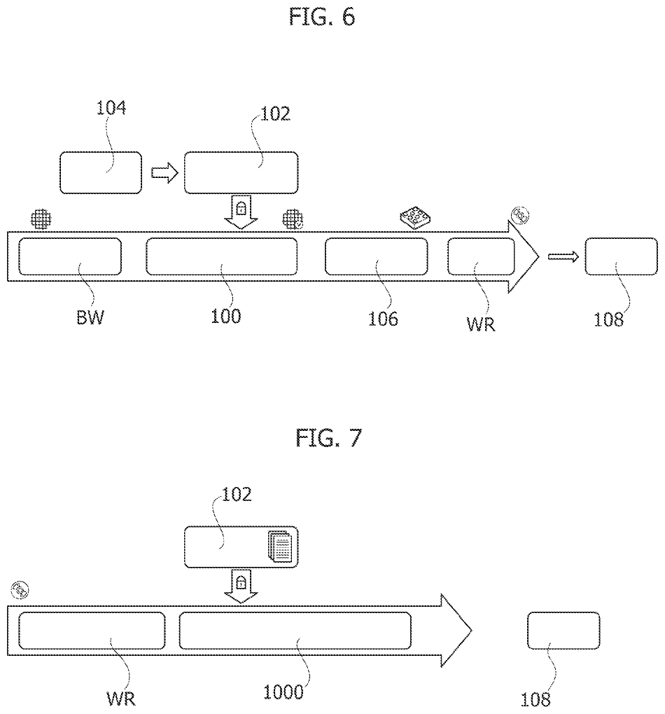

FIG. 6 illustrates a conventional personalization flow of a WLCSP device based on wafer-level personalization (as represented by block 100) of a bumped wafer BW based on design data such as operating system, OS, profile and data generation information 102 as provided by a source such as a telecom operator 104.

As illustrated in FIG. 6, the results of wafer-level personalization of block 100 can be subjected to singulation (wafer dicing) as represented by block 106, after which WLCSP devices in reel form WR can be made available to delivery as represented by block 108.

FIG. 7 illustrates a personalization flow of a WLCSP device according to embodiments of the present disclosure.

In such a flow, personalization as represented by block 1000 in FIG. 7 can be performed based on personalization information 102 on pick and place equipment as illustrated in FIGS. 5A to 5E, operating on WLCSP devices that already are in reel form WR in view of delivery as represented by block 108.

Without prejudice to the underlying principles, the details and embodiments may vary, even significantly, with respect to what has been described by way of example only without departing from the extent of protection.

A method, may be summarized as including: aligning electrical contact formations (S) in an array of electrical contact formations on a first surface (D1) of a semiconductor device (D) with electrically conductive pins in an array of electrically conductive pins (P), wherein the semiconductor device (D) includes, opposite the first surface (D1), a second surface (D2) protected by a protection layer (A), wherein the method includes: aligning the semiconductor device (D) to a first alignment member (12) by exposing said protected second surface (D2) of the semiconductor device (D) to a chamfered surface (C12) in the first alignment member (12), and aligning the first alignment member (12) with a second alignment member (14) having the array of electrically conductive pins (P) aligned therewith, wherein the array of electrical contact formations(S) is aligned with respect to the array of electrically conductive pins (P) in response to the first (12) and second (14) alignment members being mutually aligned (R1, R2).

The chamfered surface (C12) in the first alignment member (12) may include a tapered surface converging in a tapering direction from a first end towards a second end of the first alignment member (12), and aligning the semiconductor device (D) to the first alignment member (12) may include advancing (U) the semiconductor device (D) with respect to said chamfered surface (C12) in said tapering direction with the protected second surface (D2) exposed to said chamfered surface (C12).

The first (12) and second (14) alignment members may have complementary mating formations (R1, R2) wherein the first (12) and second (14) alignment members may be mutually aligned via said complementary mating formations (R1, R2).

The complementary mating formations (R1, R2) may include complementary mating cavities (R1) and protrusions (R2) carried by the first (12) and second (14) alignment members.

The semiconductor device (D) may include a Wafer Level Chip Scale Package (WLCSP) semiconductor device.

An apparatus (10, 12, 14) for use in performing the method, the apparatus may be summarized as including: a first alignment member (12) configured to have said semiconductor device (D) aligned therewith in response to said protected second surface (D2) of the semiconductor device (D) being exposed to a chamfered surface (C12) in the first alignment member (12), a second alignment member (14) configured to have the array of electrically conductive pins (P) aligned therewith, and alignment formations (R1, R2) configured to align the first alignment member (12) with the second alignment member (14), wherein the array of electrical contact formations(S) is aligned with respect to the array of electrically conductive pins (P) in response to the first (12) and second (14) alignment members being mutually aligned.

The chamfered surface (C12) in the first alignment member (12) may include a tapered surface converging in a tapering direction from a first end towards a second end of the first alignment member (12), and the apparatus may include a picking tool (M, 10) configured to advance (U) the semiconductor device (D) with respect to said chamfered surface (C12) in said tapering direction with the protected second surface (D2) exposed to said chamfered surface (C12).

The first (12) and second (14) alignment members may have complementary mating formations (R1, R2) wherein the first (12) and second (14) alignment members may be mutually aligned in response to said complementary mating formations (R1, R2) being mutually engaged.

The complementary mating formations may include complementary mating cavities (R1) and protrusions (R2) carried by the first (12) and second (14) alignment members.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
aligning electrical contact formations in an array of electrical contact formations on a first surface of a semiconductor device with electrically conductive pins in an array of electrically conductive pins, wherein the semiconductor device comprises, opposite the first surface, a second surface protected by a protection layer, wherein the aligning includes:
aligning the semiconductor device to a first alignment member by exposing the protected second surface of the semiconductor device to a chamfered surface in the first alignment member; and
aligning the first alignment member with a second alignment member having the array of electrically conductive pins aligned therewith, wherein the array of electrical contact formations is aligned with respect to the array of electrically conductive pins in response to the first and second alignment members being mutually aligned.

2. The method of claim 1, wherein:
the chamfered surface in the first alignment member includes a tapered surface converging in a tapering direction from a first end towards a second end of the first alignment member, and
aligning the semiconductor device to the first alignment member includes advancing the semiconductor device with respect to the chamfered surface in the tapering direction with the protected second surface exposed to the chamfered surface.

3. The method of claim 1, wherein the first and second alignment members have complementary mating formations wherein the first and second alignment members are mutually aligned via the complementary mating formations.

4. The method of claim 3, wherein the complementary mating formations include complementary mating cavities and protrusions carried by the first and second alignment members.

5. The method of claim 1, wherein the semiconductor device includes a Wafer Level Chip Scale Package semiconductor device.

6. An apparatus, comprising:
a semiconductor device having a first surface and a protected second surface, the first surface including an array of electrical contact formations and an array of electrically conductive pins;
a first alignment member aligned with the semiconductor device in response to the protected second surface of the semiconductor device being exposed to a chamfered surface in the first alignment member;
a second alignment member aligned with the array of electrically conductive pins; and
alignment formations aligned with the first alignment member with the second alignment member, wherein the array of electrical contact formations is aligned with respect to the array of electrically conductive pins in response to the first and second alignment members being mutually aligned.

7. The apparatus of claim 6, wherein:
the chamfered surface in the first alignment member includes a tapered surface converging in a tapering direction from a first end towards a second end of the first alignment member, and
the apparatus includes a picking tool configured to advance the semiconductor device with respect to the chamfered surface in the tapering direction with the protected second surface exposed to the chamfered surface.

8. The apparatus of claim 6, wherein the first and second alignment members have complementary mating formations wherein the first and second alignment members are mutually aligned in response to the complementary mating formations being mutually engaged.

9. The apparatus of claim 8, wherein the complementary mating formations include complementary mating cavities and protrusions carried by the first and second alignment members.

10. A method, comprising:
aligning electrical contact formations on a first surface of a semiconductor device with electrically conductive pins;
aligning the semiconductor device to a first alignment member by exposing a protected second surface of the semiconductor device to a chamfered surface in the first alignment member; and
mutually aligning the first alignment member with a second alignment member having the electrically conductive pins thereby aligning the electrical contact formations with the electrically conductive pins.

11. The method of claim 10 wherein the chamfered surface includes a tapered surface converging in a tapering direction from a first end towards a second end of the first alignment member.

12. The method of claim 11 wherein aligning the semiconductor device to the first alignment member includes advancing the semiconductor device with respect to the chamfered surface in the tapering direction.

13. The method of claim 12 wherein the protected second surface is exposed to the chamfered surface.

14. The method of claim 10, wherein the first and second alignment members have complementary mating formations wherein the first and second alignment members are mutually aligned via the complementary mating formations.

15. The method of claim 14, wherein the complementary mating formations include complementary mating cavities and protrusions carried by the first and second alignment members.

16. The method of claim 10 wherein the first alignment member includes a plurality of cavities in a third surface facing the second alignment member.

17. The method of claim 16 wherein the second alignment member includes a plurality of protrusions facing and configured to interact and align with the plurality of cavities.
